(19) United States
(12) Patent Application Publication
(10) Pub. No.: US 2008/0085600 A1
(43) Pub. Date: Apr. 10, 2008

(54) METHOD OF FORMING LITHOGRAPHIC AND SUB-LITHOGRAPHIC DIMENSIONED STRUCTURES

(76) Inventors: Toshiharu Furukawa, Essex Junction, VT (US); David Vaclav Horak, Essex Junction, VT (US); Charles William Koburger, Delmar, NY (US)

Correspondence Address: SCHMEISER, OLSEN & WATTS, 22 CENTURY HILL DRIVE, SUITE 302, LATHAM, NY, 12110, US

(21) Appl. No.: 11/548,009

(22) Filed: Oct. 10, 2006

(51) Int. Cl. H01L 21/4763

(52) U.S. Cl. 438/637

(57) ABSTRACT

A method of forming lithographic and sub-lithographic dimensioned structures. The method includes forming a mandrel layer on a top surface of an underlying layer and then forming a masking layer on a top surface of the mandrel layer; patterning the masking layer into a pattern of islands; transferring the pattern of islands into the mandrel layer to form mandrel islands, the top surface of the underlying layer exposed in spaces between the mandrel islands; forming first spacers on sidewalls of the mandrel islands; removing the mandrel islands, the top surface of the underlying layer exposed in spaces between the first spacers; forming second spacers on sidewalls of the first spacers; and removing the first spacers, the top surface of the underlying layer exposed in spaces between the second spacers.

### FIELD OF THE INVENTION

The present invention relates to the field of integrated circuit fabrication; more specifically, it relates to a method for forming lithographic and sub-lithographic structures.

### BACKGROUND OF THE INVENTION

As the performance of integrated circuits has increased and size of integrated circuits has decreased, the sizes of the structures making up the integrated circuit have also decreased. These structures are defined lithographically and there is a minimum feature size that can be defined by lithographic processes. While lithographic technology has and continues to reduce this minimum feature size by employing shorter wavelength exposure radiation and increasing effective numerical aperture, the pace of this reduction in minimum feature size has begun to slow. At the same time, while some structures impart a benefit to integrated circuits the smaller they get, other structures do not. Also, for some structures, it is better that they have dimensions less than the lithographic minimum feature size. Therefore, there is a need for a method for forming structures having lithographic and sub-lithographic dimensions.

### SUMMARY OF THE INVENTION

A first aspect of the present invention is a method, comprising: forming a mandrel layer on a top surface of an underlying layer and then forming a masking layer on a top surface of the mandrel layer; patterning the masking layer into a pattern of islands;

transferring the pattern of islands into the mandrel layer to form mandrel islands, the top surface of the underlying layer exposed in spaces between the mandrel islands; forming first spacers on sidewalls of the mandrel islands; removing the mandrel islands, the top surface of the underlying layer exposed in spaces between the first spacers; forming second spacers on sidewalls of the first spacers; and removing the first spacers, the top surface of the underlying layer exposed in spaces between the second spacers.

A second aspect of the present invention is a method comprising: forming one or more mandrel islands on a top surface of an underlying layer; forming first spacers on sidewalls of the one or more mandrel islands and then removing the one or more mandrel islands, the spacers defining a first pattern; forming second spacers on sidewalls of the first spacers and then removing the first spacers, the second spacers defining a second pattern, the second pattern a reverse of the first pattern where the second spacers had completely covered the underlying layer between adjacent first spacers; and etching trenches into the underlying layer in regions of the underlying layer where the underlying layer is not protected by the second spacers.

A third aspect of the present invention is a method comprising: forming a mandrel layer on a top surface of an underlying layer and then forming a first photoresist layer on a top surface of the mandrel layer; performing a first photolithographic process to form the first photoresist layer into a pattern of first photoresist regions; transferring the pattern of first photoresist regions into the mandrel layer to form mandrel islands, the top surface of the underlying layer exposed in spaces between the mandrel islands; removing the first photoresist regions; forming first spacers on sidewalls of the mandrel islands; removing the mandrel islands, the top surface of the underlying layer exposed in spaces between the first spacers; forming second spacers on sidewalls of the first spacers; removing the first spacers, the top surface of the underlying layer exposed in spaces between the second spacers; forming a second photoresist layer on the top surface of the second spacers; and performing a second photolithographic process to form the second photoresist layer into a pattern of second photoresist regions, selected regions of the second photoresist regions overlapping selected regions of the second spacers, first regions of the underlying layer exposed between the second spacers, and second regions of the underlying layer exposed in spaces between the second photoresist regions.

### BRIEF DESCRIPTION OF DRAWINGS

The features of the invention are set forth in the appended claims. The invention itself, however, will be best understood by reference to the following detailed description of an illustrative embodiment when read in conjunction with the accompanying drawings, wherein:

FIGS. 1A, 2A, 3A, 4A, 5A, 6A, 7A, 8A, 9A and 10A are top views, FIGS. 1B, 2B, 3B, 4B, 5B, 6B, 7B, 8B, 9B and 10B are cross-sectional views through respective lines 1B-1B, 2B-2B, 3B-3B, 4B-4B, 5B-5B, 6B-6B, 7B-7B, 8B-8B, 9B-9B and 10B-10B of respective FIGS. 1A, 2A, 3A, 4A, 5A, 6A, 7A, 8A, 9A and 10A and FIGS. 8C and 9C are cross-sectional views through respective lines 8C-8C and 9C-9C of respective FIGS. 8A and 9A illustrating steps in the fabrication of a structure according to embodiments of the present invention; and

FIG. 11A is a top view and FIG. 11B is a cross-sectional view through line 11B-11B of FIG. 11A illustrating a further step in the fabrication of a structure according to embodiments of the present invention.

### DETAILED DESCRIPTION OF THE INVENTION

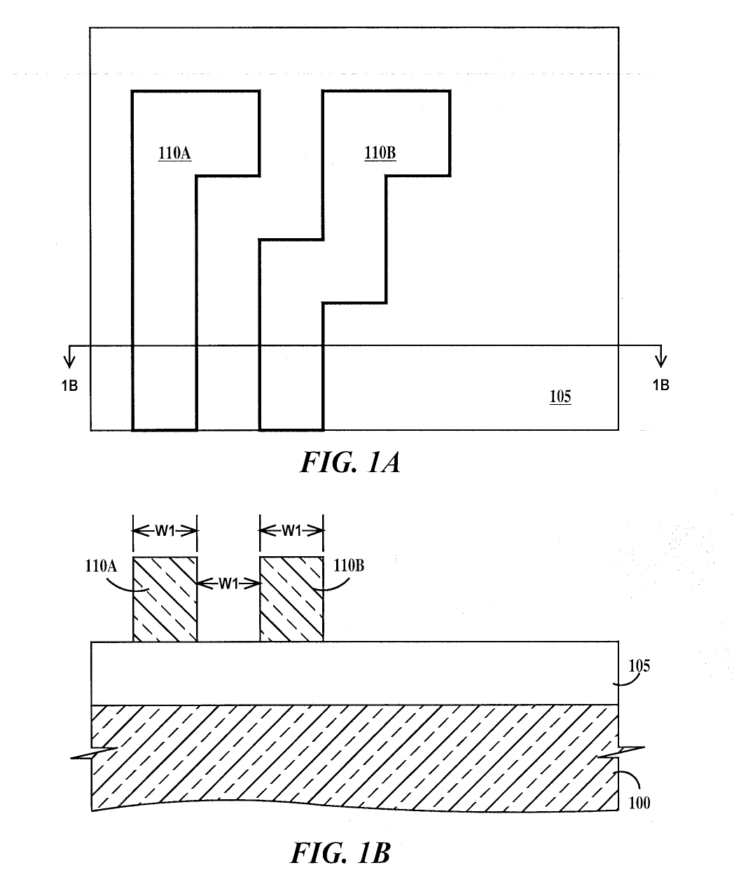

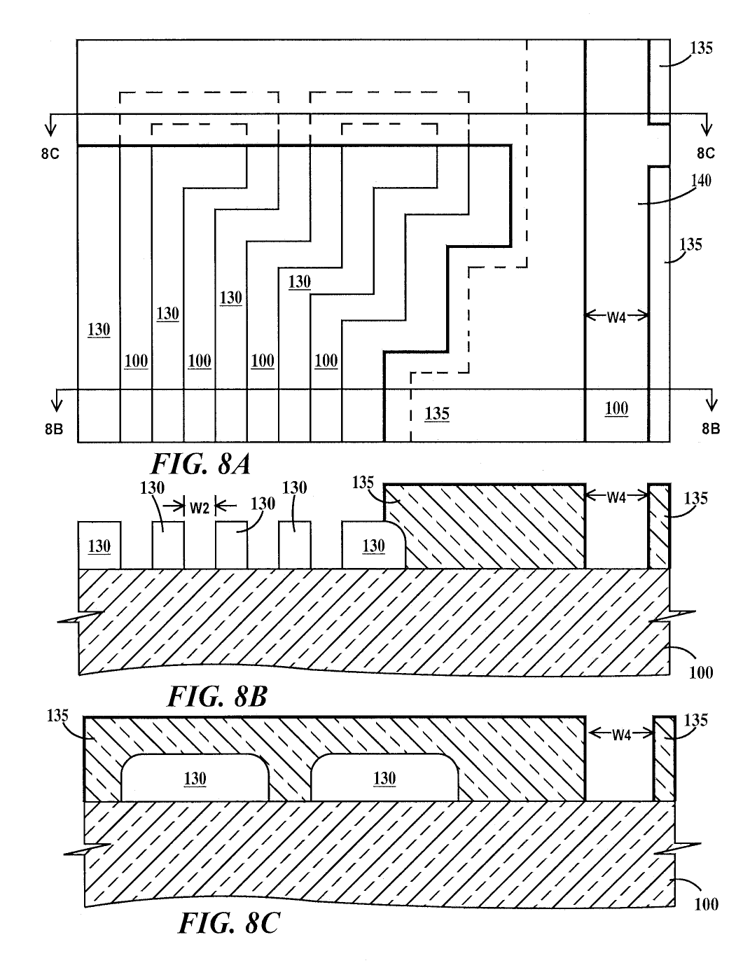

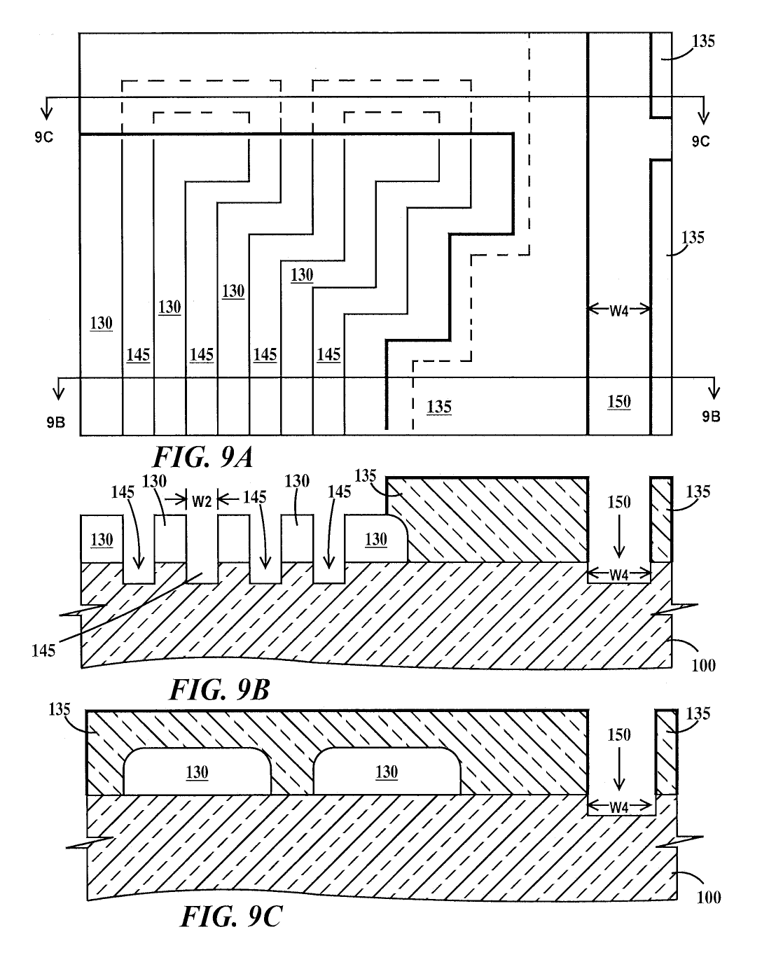

FIGS. 1A, 2A, 3A, 4A, 5A, 6A, 7A, 8A, 9A and 10A are a top views, FIGS. 1B, 2B, 3B, 4B, 5B, 6B, 7B, 8B, 9B and 10B are cross-sectional views through respective lines 1B-1B, 2B-2B, 3B-3B, 4B-4B, 5B-5B, 6B-6B, 7B-7B, 8B-8B, 9B-9B and 10B-10B of respective FIGS. 1A, 2A, 3A, 4A, 5A, 6A, 7A, 8A, 9A and 10A and FIGS. 8C and 9C are cross-sectional views through respective lines 8C-8C and 9C-9C of respective FIGS. 8A and 9A illustrating steps in the fabrication of a structure according to embodiments of the present invention.

In FIGS. 1A and 1B, formed on a top surface of an underlying layer 100 is a mandrel layer 105. In one example underlying layer 100 is an interlevel dielectric layer (ILD) which itself is formed on a semiconductor substrate (not shown). Formed on a top surface of mandrel layer 105 are photoresist regions 110A and 110B. Photoresist regions 110A and 110B are formed by applying a photoresist layer to the top surface of mandrel layer, exposing the photoresist layer to actinic radiation through a photomask having a pattern of islands 110A and 110B and then developing the exposed photoresist layer to form islands 110A and 110B.

Photoresist resist islands 110A and 110B have a width W1 and are spaced apart a distance W1 (through section 1A-1A). W1 is the minimum dimension of a line/space printable by the photolithography process (described supra) used to form photoresist regions 110A and 110B. In one example W1 is 60 nm or less.

In one example, underlying layer 100 comprises a low-K (dielectric constant) material, examples of which include but are not limited to hydrogen silsesquioxane polymer (HSQ), methyl silsesquioxane polymer (MSQ), SiLK™ (polyphenylene oligomer) manufactured by Dow Chemical, Midland, Tex., Black Diamond™ (methyl doped silica or SiOₓ(CH₃)_{y} or SiCₓO_{y}H_{y} or SiOCH) manufactured by Applied Materials, Santa Clara, Calif., organosilicate glass (SiCOH), and porous SiCOH. A low-K dielectric material has a relative permittivity of about 2.7 or less. In one example, underlying layer 100 comprises silicon dioxide (SiO₂), silicon nitride (Si₃N₄), silicon carbide (SiC), silicon oxy nitride (SiON), silicon oxy carbide (SiOC), organosilicate glass (SiCOH), plasma-enhanced silicon nitride (PSiNₓ) or NBLok (SiC(N,H)). In one example, underlying layer 100 is about 100 nm to about 200 nm thick.

In one example, mandrel layer 105 comprises amorphous silicon. In one example, mandrel layer 105 is about 50 nm to about 200 nm thick.

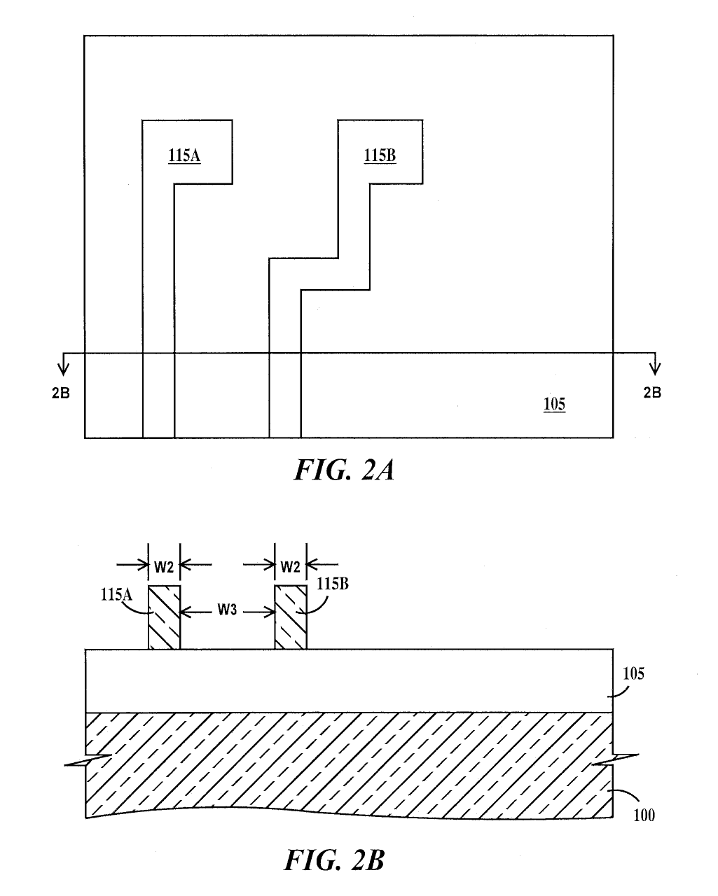

In FIGS. 2A and 2B, photoresist regions 110A and 110B (see FIGS. 1A and 1B) are optionally trimmed to form respective trimmed photoresist regions 115A and 115B. In one example, trimming is accomplished by a plasma etch process, for example, an oxygen-based plasma etch. Trimmed photoresist resist islands 115A and 115B have a width W2 and are spaced apart a distance W3 (through section 2A-2A), where advantageously W2 equals W1 divided by two and W3 is thrice W2. However, W2 can have any greater than zero and value less than W1 with W3 increasing by the absolute difference between W1 and W2. One advantage of performing trimming is to pack the features subsequently formed and described infra more closely, allowing equal sub-lithographic dimensions between more of the features.

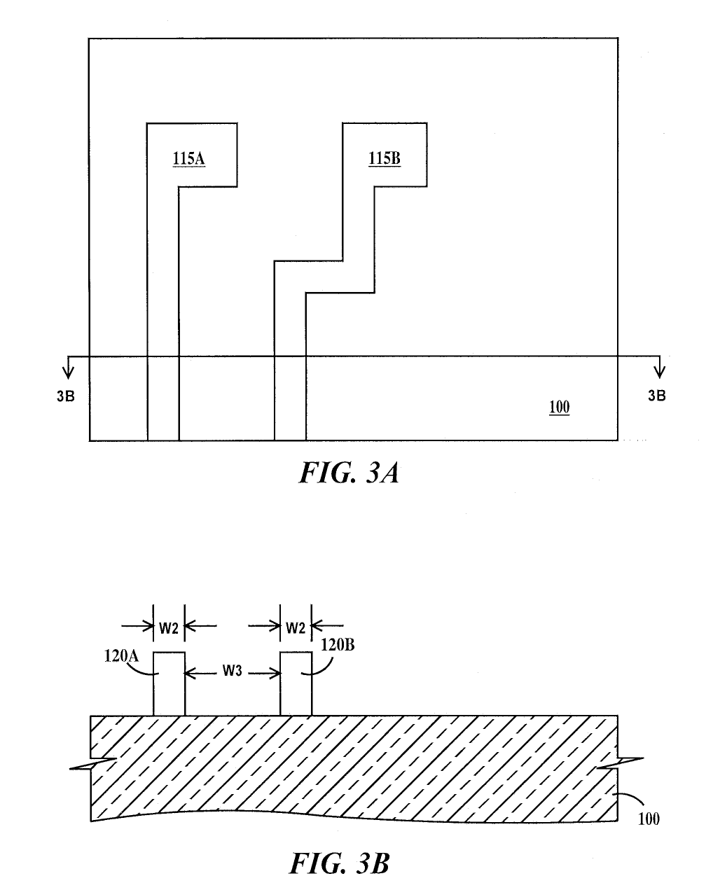

In FIGS. 3A and 3B, the pattern of trimmed photoresist regions 115A and 115B (see FIGS. 2A and 2B) is transferred into mandrel layer 105 (see FIG. 2B) by etching (for example, using a reactive ion etch (RIE) process) away all of the mandrel layer not protected by the photoresist regions. Then the trimmed photoresist regions are removed leaving respective mandrels 120A and 120B having widths of about W2 and spaced apart about a distance W3.

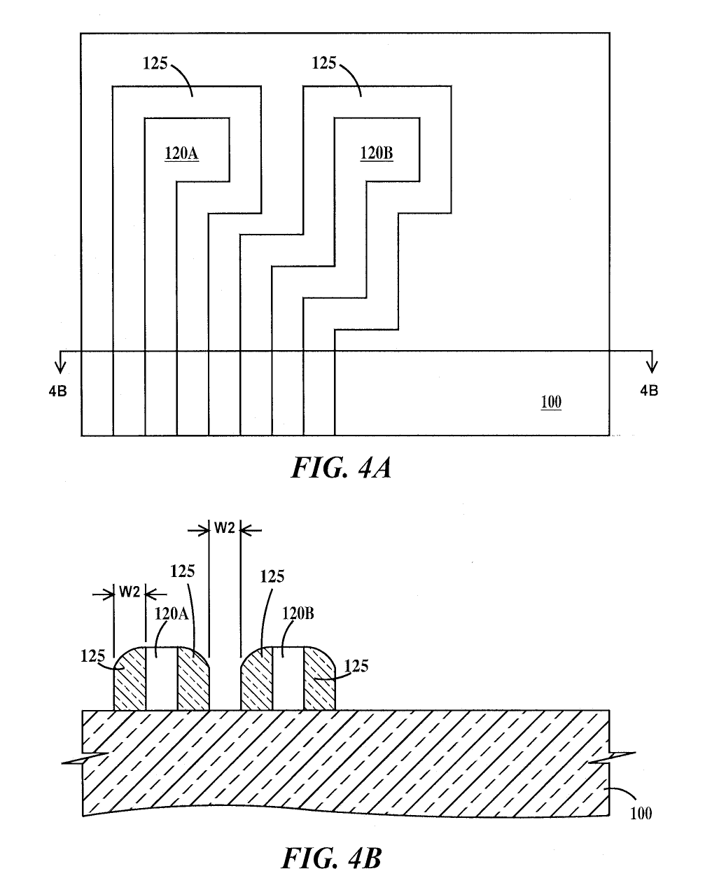

In FIGS. 4A and 4B, spacers 125 are formed on the sidewalls of mandrels 120A and 120B. Spacers 125 may be formed by deposition of a conformal layer, followed by a directional RIE (perpendicular to the top surface of underlying layer 100) to remove the conformal layer from all horizontal surfaces (e.g. surfaces parallel to the top surface of underlying layer 100). In one example, spacers 125 comprises silicon nitride. In one example, spacers 125 advantageously have a sidewall thickness (in the horizontal direction) of about W2, which makes the space between respective spacers 125 on opposing sidewalls of mandrels 120A and 120B about W2. However, the sidewall thickness of spacers 125 may be less than or greater than W2.

If photoresist regions 110A and 10B (see FIGS. 1A and 1B) were not trimmed as illustrated in FIGS. 2A and 2B and describes supra, spacers 125 may still have a width W2, but the space between adjacent spacers 125 need not be W2, the space could be greater or less than W2. However, W2 is still a sub-lithographic dimension.

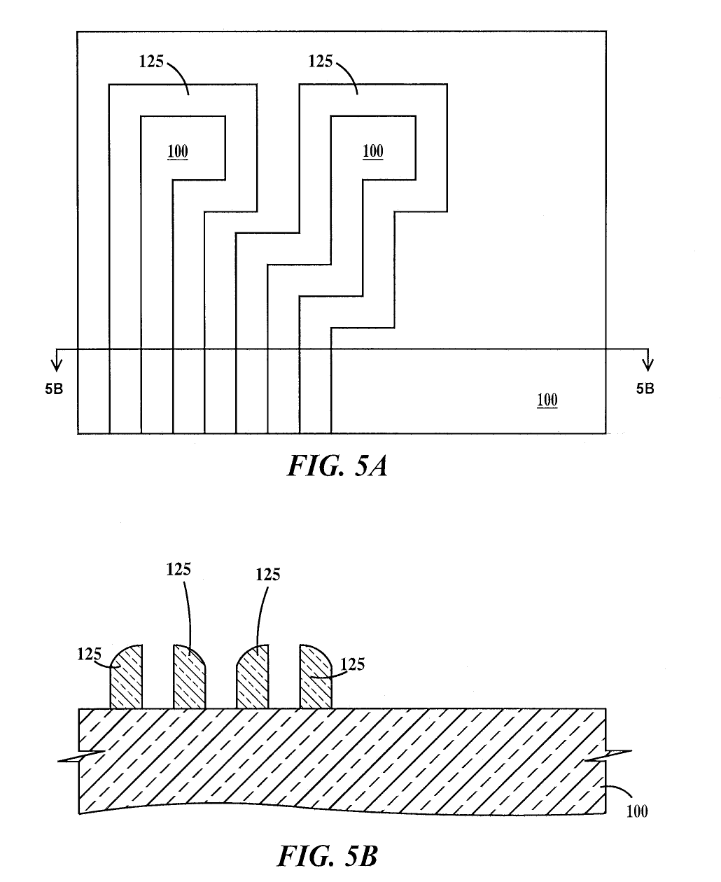

In FIGS. 5A and 5B, mandrels 120A and 120B (see FIGS, 4A and 4B) are removed, for example by wet or dry etching, leaving spacers 125. After removing mandrels 120A and 120B, spacers 125 form a pattern defined by the sidewalls of the mandrels.

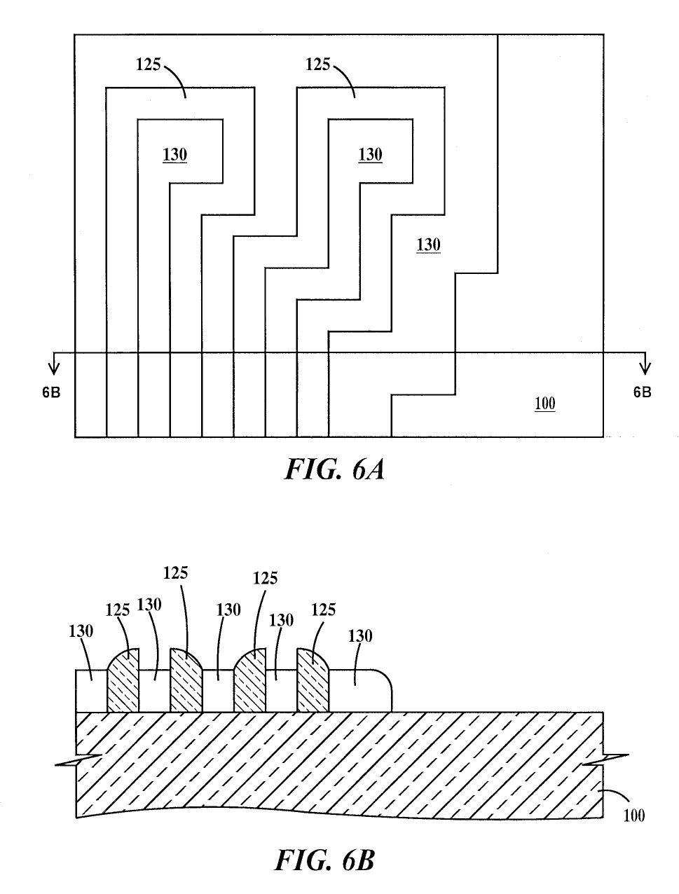

In FIGS. 6A and 6B, second spacers 130 are formed on the sidewalls of spacers 125. Between adjacent spacers 125, spacers 130 overlap so as to fully cover underlying layer 100. In one example, spacers 130 advantageously have a sidewall thickness (in the horizontal direction) of about 0.9 times W1. In one example, spacers 130 comprise amorphous silicon. The sidewall thickness of spacers 130 should be great enough to allow landing of the edge of a block mask as illustrated in FIGS. 8A, 8B and 8C and described infra.

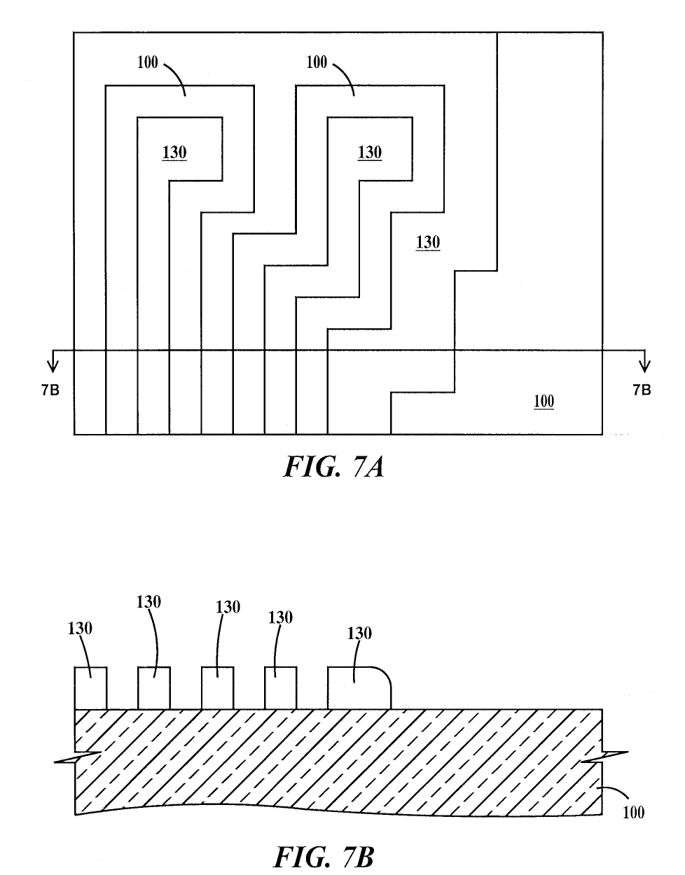

In FIGS. 7A and 7B, spacers 125 (see FIGS. 6A and 6B) are removed, for example, by wet or dry etching, leaving spacers 130. After removing spacers 125, spacers 130 form a pattern that in dense pattern regions is the reverse of the pattern formed by spacers 125. In dense pattern regions the pattern formed by spacers 130 is a reverse of the pattern formed by spacers 125 because all regions of underlying layer 100 that were not covered by spacers 125 are covered by spacers 130 and all regions of underlying layer 100 that were covered by spacers 125 are not covered by spacers 130. Dense pattern regions are defined as those regions where spacers 125 are sufficiently close together that spacers 130 completely cover underlying layer 100 between adjacent spacers 125. Alternatively, dense pattern regions can be defined as regions where the distance between adjacent spacers 125 is no more than about twice the thickness of spacers 130 on the sidewalls of spacers 125.

In FIGS. 8A, 8B and 8C, a second photolithographic process is performed, forming photoresist regions 135. In the illustrated example photoresist regions 135 overlap the outermost edges of spacers 130 and cover selected regions of underlying layer 100 outside of the outermost spacers 130. Regions 150 (see FIG. 9A) of underlying layer 100 are also exposed where edges of photoresist regions 135 are landed directly on the top surface of the underlying layer. Regions 150 have a width W4 (in the direction of section line 8B-8B). W4 is greater than W2. In one example, W4 is at least equal to or greater than W1. In one example, W4 is equal to or greater than the minimum dimension of a line/space printable by the photolithography process used to form photoresist regions 135 or photoresist regions I 10A and I 10B (see FIGS. 1A and 1B). Photoresist regions 135 also cover portions of underlying layer 100 inside of the outermost spacers 130, where the closed-loop topology of spacers 130 would otherwise and undesirably lead to continuous loops of exposed underlying layer 100. The dashed lines of FIG. 8A show the spacer 130 where it extends under photoresist regions 135.

In FIGS. 9A, 9B and 9C, spacers 130 and photoresist regions 135 are used as an etch mask to form trenches 145 and 150 into underlying layer 100. In one example, trenches 145 and 150 are formed by RIE. Trenches 145 have a width about equal to W2 and trench 150 has a width about equal to W4 (in the direction of section line 9B-9B). The dashed lines of FIG. 9A show the spacer 130 where it extends under photoresist regions 135.

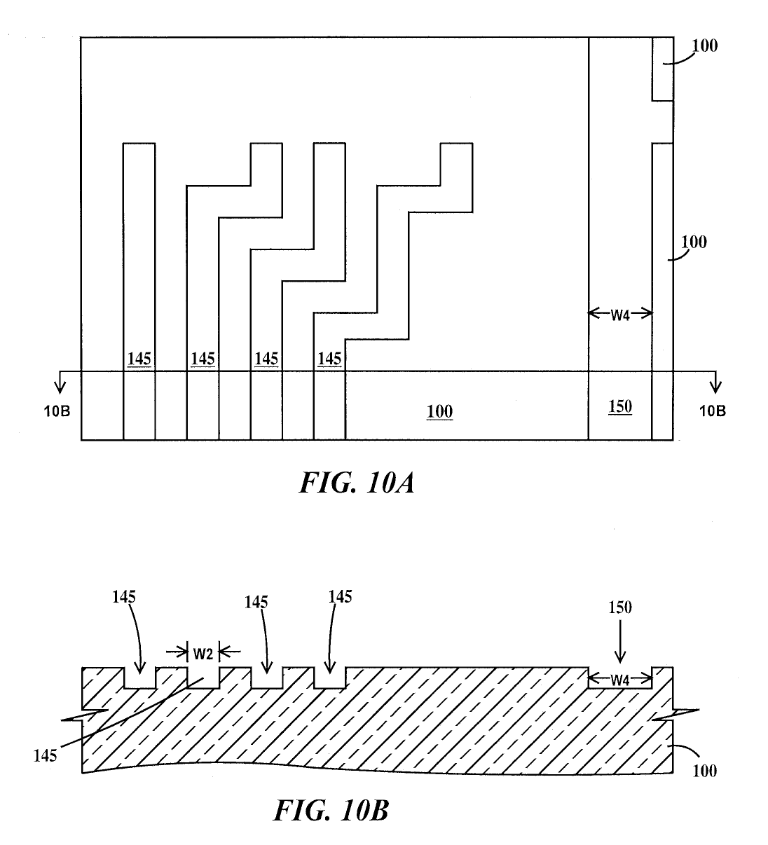

In FIGS. 10A and 10B, photoresist regions 135 and spacers 130 (see FIGS. 9A, (B and 9C) are removed, by wet or dry etching, leaving trenches 145 and 150 in underlying layer 100. Since trenches 145 have a width W2 which is smaller than a minimum photolithographic dimension and trenches 150 have a width W4 which is equal to or greater than a minimum photolithographic dimension, both lithographic and sub-lithographic dimensioned structures have been formed simultaneously using only two photolithographic steps. It should be noted that photoresist regions 135 (see FIG. 9A) have prevented interconnection of adjacent trenches 145 by preventing etching of underlying layer 100 between spacers 130 where the islands fill the spaces between spacers 130 (see the dashed lines of FIGS. 8A and 9A).

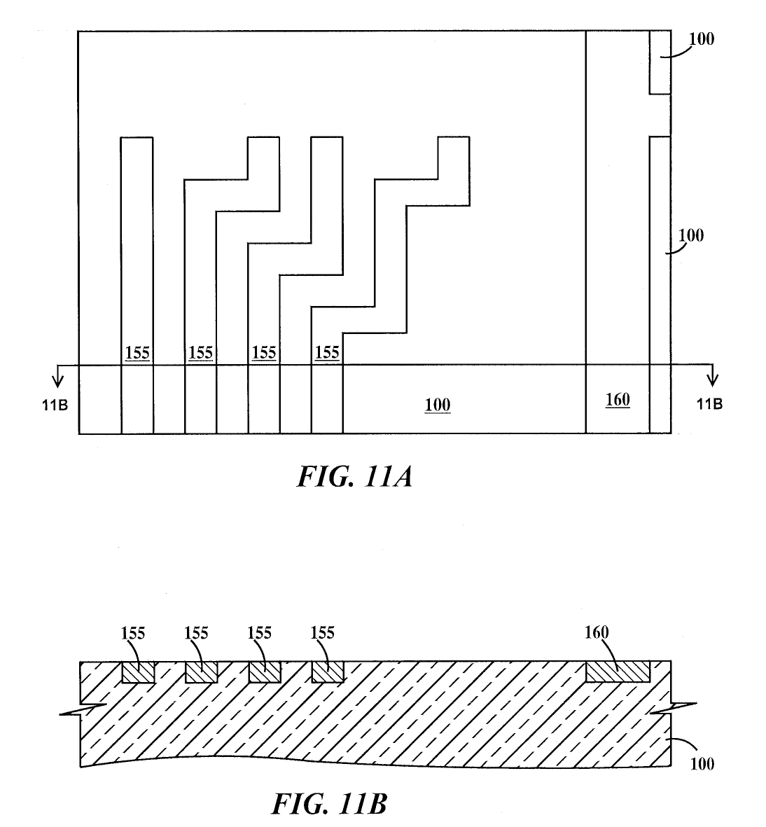

FIG. 11A is a top view and FIG. 11B is a cross-sectional view through line 11B-11B of FIG. 11A illustrating a further step in the fabrication of a structure according to embodiments of the present invention. In FIGS. 11A and 11B, trenches 145 and 150 (see FIGS. 10A and 10B) are filled with a electrical conductor to form respective wires 155 and 160. In one example, wires 155 and 160 comprise copper, tungsten, tantalum, tantalum nitride, titanium, titanium nitride, aluminum or combinations thereof and are formed by plating a layer of copper on underlying layer 100 that is thicker than trenches to be filled and then performing a chemical mechanical polish, removing excess copper in order to coplanarize top surfaces of wires 155 and 160 with the top surface of underlying layer 100. Wires 155 and 160 are damascene wires. Wires 155 and 160 may include an electrically conductive liner on the sidewalls and bottom surface of the wires.

Thus, the embodiments of the present invention provide a method for forming structures having lithographic and sub-lithographic dimensions.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A method, comprising:
forming a mandrel layer on a top surface of an underlying layer and then forming a masking layer on a top surface of said mandrel layer;
patterning said masking layer into a pattern of islands;
transferring said pattern of islands into said mandrel layer to form mandrel islands, said top surface of said underlying layer exposed in spaces between said mandrel islands;
forming first spacers on sidewalls of said mandrel islands;
removing said mandrel islands, said top surface of said underlying layer exposed in spaces between said first spacers;
forming second spacers on sidewalls of said first spacers; and
removing said first spacers, said top surface of said underlying layer exposed in spaces between said second spacers.

2. The method of claim 1, further including:
prior to said transferring, reducing dimensions of said islands in directions parallel to said top surface of said underlying layer.

3. The method of claim 2, wherein said patterning includes performing a photolithographic process and said dimensions, after reduction, are less than a minimum dimension of a line/space printable by said photolithographic process.

4. The method of claim 1, further including, etching trenches into said underlying layer in regions of said underlying layer not protected by said second spacers.

5. The method of claim 4, wherein said patterning includes performing a photolithographic process and at least one dimension of at least one of said trenches in a direction parallel to said top surface of said underlying layer being less than a minimum dimension of a line/space printable by said photolithographic process.

6. The method of claim 4, wherein said undying layer comprises dielectric material and said method further includes removing said second spacers and filling said trenches with an electrically conductive material.

7. The method of claim 4, further including:
prior to said etching, forming an additional masking layer on additional regions of said underlying layer, said additional masking layer preventing etching of said underlying layer in said additional regions.

8. The method of claim 1, further including:
after said removing said first spacers, forming an additional masking layer on a top surface of said underlying layer and on said second spacers;
patterning said additional masking layer into a pattern of additional islands, selected regions of said additional islands overlapping selected regions of said second spacers, first regions of said underlying layer exposed between said second spacers, and second regions of said underlying layer exposed in spaces between said additional islands.

9. The method of claim 8, further including, etching first trenches into said underlying layer in said first regions of said underlying layer not protected by said second spacers and etching second trenches into said second regions of said underlying layer not protected by said additional islands.

10. The method of claim 8, wherein said patterning of said masking layer includes performing a first photolithographic process and said patterning of said additional masking layer includes performing a second photolithographic process, at least one dimension of at least one of said first trenches in a direction parallel to said top surface of said underlying layer being less than a minimum dimension of a line/space printable by said first photolithographic process and all dimensions of said second trenches in directions parallel to said top surface of said underlying layer being equal to greater than said minimum dimension of said line/space printable by said first photolithographic process.

11. The method of claim 8, wherein said underlying layer comprises dielectric material and further including removing said second spacers and said additional islands and filling said first and second trenches with an electrically conductive material.

12. A method comprising:
forming one or more mandrel islands on a top surface of an underlying layer;
forming first spacers on sidewalls of said one or more mandrel islands and then removing said one or more mandrel islands, said first spacers defining a first pattern;
forming second spacers on sidewalls of said first spacers and then removing said first spacers, said second spacers defining a second pattern, said second pattern a reverse of said first pattern where said second spacers had completely covered said underlying layer between adjacent first spacers; and
etching trenches into said underlying layer in regions of said underlying layer where said underlying layer is not protected by said second spacers.

13. The method of claim 12, further including:
filling said trenches with a fill material.

14. The method of claim 13, wherein said underlying layer comprises dielectric material and said fill material is electrically conductive.

15. The method of claim 12, wherein said one or more mandrel islands are formed using a photolithographic process and at least one dimension of at least one of said trenches in a direction parallel to said top surface of said underlying layer is less than a minimum dimension of a line/space printable by said photolithographic process.

16. The method of claim 12, further including:
performing a first photolithographic process to form said mandrel islands;
between said removing said first spacers and said etching, performing a second photolithographic process, said second photolithographic process forming protective islands, selected regions of said protective islands overlapping selected regions of said second spacers, additional regions of said underlying layer exposed in spaces between said protective islands; and
simultaneously with said etching trenches, etching additional trenches in regions of said underlying layer exposed between said protective islands, at least one dimension of at least one of said trenches in a direction parallel to said top surface of said underlying layer being less than a minimum dimension of a line/space printable by said first photolithographic process and all dimensions of said additional trenches in directions parallel to said top surface of said underlying layer being equal to or greater than said minimum dimension of said line/space printable by said first photolithographic process.

17. A method comprising:
forming a dielectric mandrel layer on a top surface of an underlying layer and then forming a first photoresist layer on a top surface of said mandrel layer;
performing a first photolithographic process to form said first photoresist layer into a pattern of first photoresist regions;
transferring said pattern of first photoresist regions into said mandrel layer to form mandrel islands, said top surface of said underlying layer exposed in spaces between said mandrel islands;
removing said first photoresist regions;
forming first spacers on sidewalls of said mandrel islands;
removing said mandrel islands, said top surface of said underlying layer exposed in spaces between said first spacers;
forming second spacers on sidewalls of said first spacers;
removing said first spacers, said top surface of said underlying layer exposed in spaces between said second spacers;
forming a second photoresist layer on said top surface of said mandrel layer; and
performing a second photolithographic process to form said second photoresist layer into a pattern of second photoresist regions, selected regions of said second photoresist regions overlapping selected regions of said second spacers, first regions of said underlying layer exposed between said second spacers, and second regions of said underlying layer exposed in spaces between said second photoresist regions.

18. The method of claim 17, further including:
prior to said transferring, reducing dimensions of said first photoresist regions in directions parallel to said top surface of said underlying layer, at least one dimension of at least one of said photoresist regions being less than a minimum dimension of a line/space printable by said first photolithographic process.

19. The method of claim 17, further including:
etching first trenches into said underlying layer in said first regions of said underlying layer not protected by said second spacers, at least one dimension of at least one of said trenches in a direction parallel to said top surface of said underlying layer being less than a minimum dimension of a line/space printable by said first photolithographic process; and
etching second trenches into said second regions of said underlying layer not protected by said second photoresist regions, and all dimensions of said second trenches in directions parallel to said top surface of said underlying layer being equal to greater than said minimum dimension of said line/space printable by said first photolithographic process.

20. The method of claim 19, further including:
filling said first and second trenches with an electrical conductor comprising copper, tungsten, tantalum, tantalum nitride, titanium, titanium nitride, aluminum or combinations thereof, and
wherein said underlying layer comprises hydrogen silsesquioxane polymer, methyl silsesquioxane polymer, polyphenylene oligomer, methyl doped silica, organosilicate glass, porous organosilicate glass, silicon dioxide, silicon nitride, silicon carbide, silicon oxy nitride, silicon oxy carbide, organosilicate glass, plasma-enhanced silicon nitride or NBLok.
